(19) United States
(12) Patent Application Publication
(10) Pub. No.: US 2026/0026032 A1
(43) Pub. Date: Jan. 22, 2026

(54) METAL GATED LIGHTLY DOPED DRAIN STRING DRIVER DEVICE AND METHOD THEREOF

(71) Applicant: Micron Technology, Inc., Boise, ID (US)

(72) Inventor: Michael A. Smith, Boise, ID (US)

(21) Appl. No.: 19/275,531

(22) Filed: Jul. 21, 2025

Related U.S. Application Data
(60) Provisional application No. 63/674,264, filed on Jul. 22, 2024.

(51) Int. Cl. H10D 30/60; H10D 30/01; H10D 62/10; H10D 64/00; H10D 64/27; H10D 64/66; H10D 64/68

(52) U.S. Cl. CPC H10D 30/601; H10D 30/0227; H10D 62/102; H10D 62/115; H10D 64/111; H10D 64/518; H10D 64/663; H10D 64/691; H10D 64/693

(57) ABSTRACT

A string driver device is described in this disclosure. The string driver device includes a semiconductor channel disposed in an upper portion of a semiconductor substrate and a gate dielectric layer disposed above the semiconductor channel. The string driver device also includes a source region and a drain region disposed at opposite sides of the semiconductor channel, each of the source region and the drain region having a corresponding contact disposed thereon. The string driver device further includes a gate that is disposed above the gate dielectric layer and has a first length, and a field plate layer disposed above the gate, the field plate layer having a second length larger than the first length of the gate, wherein the field plate layer includes one or more edge regions extending across the semiconductor channel edge and toward the source region or the drain region.

### CROSS-REFERENCE TO RELATED APPLICATION(S)

The present application claims priority to U.S. Provisional Patent Application No. 63/674,264, filed Jul. 22, 2024, the disclosure of which is incorporated herein by reference in its entirety.

### TECHNICAL FIELD

The present disclosure generally relates to string drivers, and more particularly relates to string driver device having metal gated lightly doped drain (LDD) or drain extension region (DER).

### BACKGROUND

String driver is an electronic device that controls the operation of a series of memory cells arranged in a string. For example, in NAND flash memory, memory cells are organized into arrays and connected in series to form a string. The string driver is responsible for selecting and manipulating these strings during read, write, or erase operations of a memory device. Further, string drivers are often integrated with or connected to charge pumps that generate required high voltages from a lower voltage power supply. The string driver regulates these voltages and ensures that they are applied accurately to the memory cells during programming and erasing operations. Moreover, string drivers can enable or disable specific strings within an array for targeted operations, allowing the memory controller to interact with specific sections of the memory array. In memory devices including NAND flash memory arrays, dynamic random-access memory (DRAM) arrays, and/or phase change memory (PCM) arrays, string driver is primaried used for data storage, wear leveling, and error correction.

One of important attributes of string driver devices is their ability to withstand high applied voltages. The ability to stand high applied voltages is a critical feature that needs to be preserved and enhanced as these devices are scaled down. This characteristic is crucial because it ensures the reliability and stability of memory operations, especially during the programming and erasing cycles which require higher voltage levels compared to read operations. However, scaling down the size of these memory devices is complex and involving reducing the physical dimensions of the memory cells and the associated string driver devices. As the dimensions of the device decrease, the electric field within the device can intensify for a given voltage, increasing the risk of breakdown. Innovating on the design of the string driver device to optimize the distribution of electric fields and device performance can help in managing the stresses induced by high voltages.

### BRIEF DESCRIPTION OF THE DRAWINGS

FIG. 1 illustrates a cross sectional view of a MOSFET device configured for high voltage string driver in accordance with various embodiments of the present technology.

FIGS. 2A to 2E illustrate cross sectional views of gated-LDD string driver device in accordance with various embodiments of the present technology.

FIGS. 3A to 3F illustrate impacts of field plate to contact distance on string driver MOSFET device performance in accordance with various embodiments of the present technology.

FIG. 4 illustrates impacts of contact to contact distance on string driver MOSFET device performance in accordance with various embodiments of the present technology.

FIG. 5 illustrates impacts of ion implantation process on string driver MOSFET device performance in accordance with various embodiments of the present technology.

FIG. 6 describes a method of fabricating metal gated-LDD string driver device according to various embodiments of the present technology.

FIG. 7 is a schematic block diagram of a system that includes a semiconductor device configured in accordance with various embodiments of the present technology.

### DETAILED DESCRIPTION

As semiconductor devices scaling continue, the development of string driver devices requires a careful balance between physical dimensions and performance capabilities. For example, there is a growing demand for these devices to become more compact while simultaneously enhancing their performance. This dual objective can be dissected into two primary goals: the reduction of the length direction pitch, known as the L-pitch, and the increase in performance that allows for a decrease in the width direction pitch, or W-pitch. The L-pitch refers to the spacing between components or circuits in the lengthwise direction of the string driver device. A reduced L-pitch is often necessary to accommodate the evolving device architecture, which is the physical layout of the semiconductor components that form an integrated circuit. This L-pitch reduction must be achieved without compromising the integrity and functionality of the device. When a string driver device operates more efficiently, it can handle more tasks within a given time frame, which can lead to a reduction in its W-pitch. The W-pitch is the spacing between components or circuits in the widthwise direction. By increasing the device's performance, it is possible to reduce the W-pitch because the device can process signals more effectively, thus requiring less physical space for the same amount of processing power.

To enhance string driver device performance, one method is to use a gate attached field plate over a lightly doped drain (LDD) region of string driver device, e.g., gated-LDD. The LDD structure, also known as the drain extension region (DER), is a critical feature in modern Metal-Oxide-Semiconductor Field-Effect-Transistors (MOSFETs) based string driver devices. The LDD is a region (e.g., a N-doped region) adjacent to the transistor's channel, where the doping concentration is lower than in the source and drain regions (e.g., N+ doped regions). A primary purpose of forming these LDD N-regions between the gate and the N+ source or drain (contact) implant regions is to enable high breakdown voltage. In addition, this gradient in doping levels is designed to mitigate the electric field at the drain, which in turn reduces hot carrier effects and improves the device's reliability. Similar concepts apply to the source region of the transistors that builds the string driver devices.

A gated-attached field plate involves the addition of a conductive field plate that is connected to the gate electrode and extends over the LDD region of string driver MOSFET. The field plate acts as an extension of the gate, influencing the electric field distribution in the LDD region. In this example, the presence of the field plate allows for a higher doping concentration in the LDD region of string driver device without compromising the device's breakdown voltage. This is because the field plate can induce a depletion region at the surface of the LDD, effectively managing the electric field and allowing for a higher doping level beneath the depleted surface. In addition, the gated-LDD (GLDD) field plate can introduce a dynamic gate coupling between the gate and the LDD region, e.g., ranging from a neutral state to an enhancement mode depending on the applied gate voltage. This dynamic gate coupling enables a more effective gate control over the channel and LDD region in string driver device. Moreover, the resistance of the LDD region can be also reduced because the induced depletion region from the gate coupling can modulate the charge carrier concentration in the LDD region, effectively reducing its resistance when the string driver MOSFET is in an ‘on’ state. The use of a gated-attached field plate over the LDD region in MOSFETs can leverage the electrostatic control of the gate to enhance the performance of the string driver devices.

One method for implementing the GLDD string driver is conducted by an extension of the polysilicon gate beyond the channel boundary, coupled with the use of a mask during the LDD implantation to define the channel region. This approach presents several technical challenges including requirement on gate oxide thickness, alignment variation, electric field management, and device scaling challenges. For example, the oxide layer thickness in the LDD region is constrained to match that of the gate oxide (Tox), which is a critical parameter in MOSFET device operation. Ensuring uniformity in oxide thickness is essential for MOSFET device reliability and performance. In addition, the GLDD process requires a precise alignment between the polysilicon gate and LDD implant masks. Any variation in this alignment can lead to significant inconsistencies in device fabrication, which in turn affects the yield and performance of the string driver devices. Further, the GLDD field plate design introduces a vertical electric field component at the edge of the gate. This vertical field has the undesirable effect of limiting the maximum lateral electric field that can be sustained in the silicon substrate. As a result, the breakdown voltage (BV) of the string driver device is reduced. To overcome this issue, it becomes necessary to increase the spacing between the edge of the polysilicon gate (the GLDD region) and the adjacent source or drain contact, which leads to an increase in the overall string driver device length and is contradictive to the L-pitch reduction requirement described above.

To solve the issues and challenges described above, the present technology introduces an innovative high voltage transistor structure for building string driver device. In particular, this transistor structure includes a field plate layer disposed above a gate electrode and longer than the gate electrode. Moreover, there are dielectric material disposed under the overhanging field plate layer to provide enhanced isolation and breakdown voltage performance. With this configuration, the gate electrode of the string driver transistor can maintain a similar length to the channel. The overhanging field plate could further induce the depletion region underneath in order to achieve a higher doping level beneath the depleted surface of the string driver transistor device.

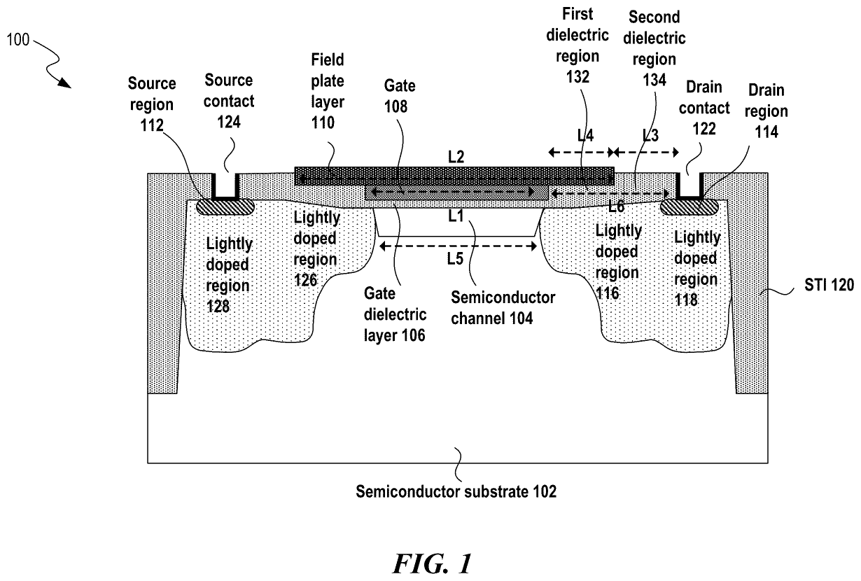

FIG. 1 illustrates a cross sectional view of a MOSFET device 100 configured for high voltage string driver in accordance with various embodiments of the present technology. The MOSFET device 100 comprises a semiconductor substrate 102, which may be made of silicon, germanium, silicon germanium, or other suitable materials. A semiconductor channel 104 is disposed in an upper portion of the semiconductor substrate 102, and may have a p-type or n-type doping depending on the desired device polarity. In addition, a gate dielectric layer 106 is disposed above the semiconductor channel 104, and may comprise silicon oxide (SiO), hafnium oxide (HfO), aluminum oxide (Al₂O₃), silico nitride (Si₃N₄), lanthanum oxide (La₂O₃), titanium oxide (TiO₂), or a combination thereof. As shown, a gate 108 is disposed above the gate dielectric layer 106, and may comprise polysilicon or other conductive materials. In this example, the gate 108 has a length L1 substantially equal to a length L5 of the semiconductor channel 104. In some other examples, the gate 108 may be equal to or larger than a length L5 of the semiconductor channel 104. Depending on voltage handling requirements, each of the length L1 of gate 108 and the length L5 of the semiconductor channel 104 can range from 700 nm to 800 nm. In some other examples, each of the length L1 of gate 108 and the length L5 of the semiconductor channel 104 can range from 500 nm to 1000 nm.

As shown in FIG. 1, a field plate layer 110 is disposed above the gate 108, and may be made of materials including tungsten, aluminum, tungsten silicon alloy, aluminum silicon alloy, or silicide. The field plate layer 110 has a length L2 larger than the length L1 of the gate 108. In addition, the field plate layer 110 includes one or more edge regions extending across the edge of the semiconductor channel 104 and toward the source region 112 or the drain region 114. Each of the one or more edge regions has a length L4 ranging from 10 nm to 1000 nm. In this example, the field plate layer 110 may act as a shield to reduce the electric field at the source region 112 or drain region 114, and improve reliability and performance of the MOSFET device 100.

In this example, the source region 112 and drain region 114 are disposed at opposite sides of the semiconductor channel 104, and may have a p-type or n-type doping opposite to that of the semiconductor channel 104. Further, a lightly doped region 128 and a lightly doped region 118 can be respectively disposed under the source region 112 and the drain region 114, and have similar doping concentrations and depths to the adjacent lightly doped gated LDD regions 126 and 116. As shown in FIG. 1, the lightly doped region 128 and the lightly doped region 126 form a single continuous region. Similarly, the lightly doped region 118 and the lightly doped region 116 form another single continuous region. Each of the source region 112 and the drain region 114 has a corresponding contact 124 and 122 disposed thereon, which may be made of metal, silicide, or other conductive materials. As shown in FIG. 1, there is a length L6 between an edge of the gate 108 and corresponding source contact 124 or drain contact 124. The length L6 can be substantially equal to or less than 700 nm.

In the MOSFET device 100, a first dielectric region 132 is disposed under the one or more edge regions of the field plate layer 110 and between the semiconductor channel edge and corresponding source contact 124 or drain contact 122. The first dielectric region 132 may comprise tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. In this example, the first dielectric region 132 may isolate the field plate layer 110 from the lightly doped regions 116 or 118, and prevent leakage currents or breakdowns during the operation of the MOSFET device 100 with a high gate voltage.

In addition, a second dielectric region 134 is disposed between the field plate layer edge and corresponding source contact 124 or drain contact 122. The second dielectric region 134 may comprise the same or different materials as the first dielectric region 132. As shown, the second dielectric region 134 has a length L3 along a horizontal direction from the field plate layer edge and corresponding source contact 124 or drain contact 122 In this example, the length L3 may range from 10 nm to 1000 nm. The second dielectric region 134 may provide additional insulation and spacing between the field plate layer 110 and the source region 112 or the drain region 114 to enhance the MOSFET device 100 breakdown performance.

The MOSFET device 100 may also comprise a shallow trench isolation (STI) region 120 disposed in the semiconductor substrate 102 and surrounding the semiconductor channel 104, the source region 112, and the drain region 114. The STI region 126 may comprise silicon oxide (SiO) or other dielectric materials, and may isolate the MOSFET device 100 from adjacent devices or structures.

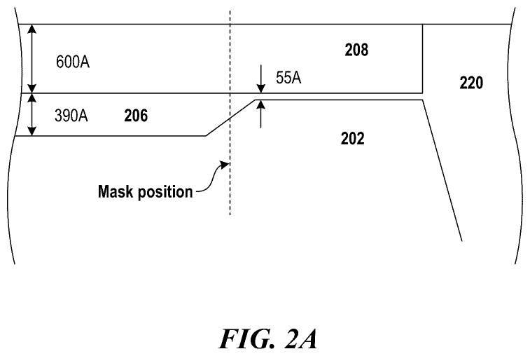

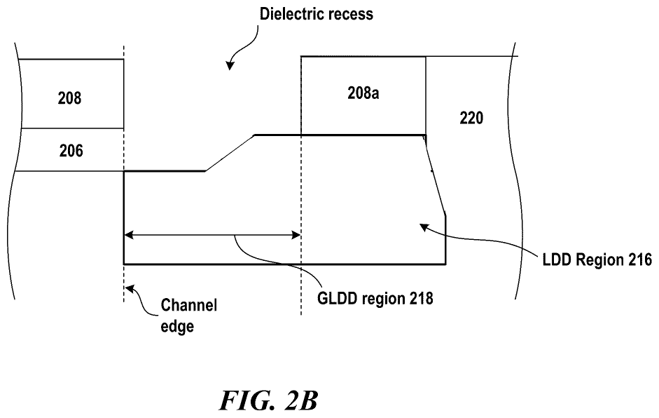

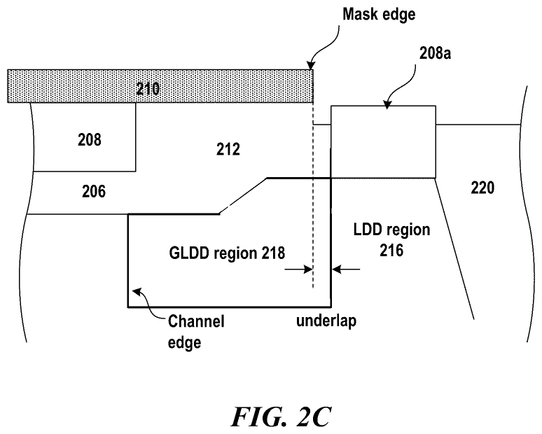

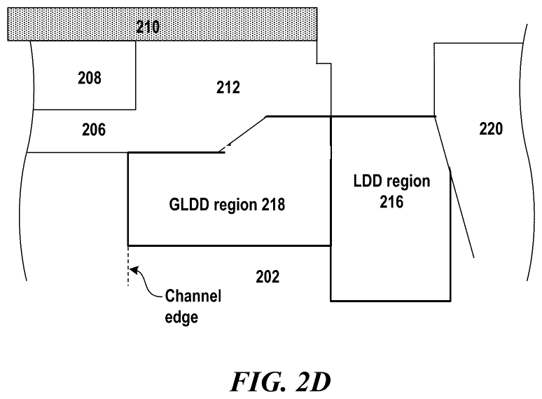

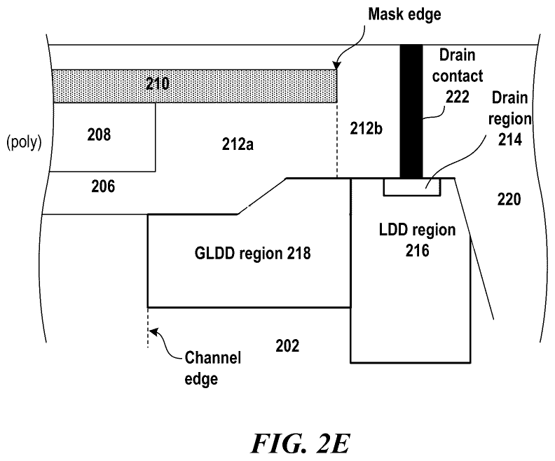

FIGS. 2A to 2E illustrate cross sectional views of GLDD string driver device 2000, e.g., the MOSFET device shown in FIG. 1, in accordance with various embodiments of the present technology. For example, FIG. 2A shows an incoming MOSFET structure that has a gate dielectric layer 206 deposited above a channel region in a substrate 202. The gate dielectric layer 206 may have a thickness around 390 Å. Above the gate dielectric layer 206, a gate electrode layer 208 can be deposited, with a thickness substantially equal to 600 Å. In some other examples, the thickness of the gate dielectric layer 206 and the gate electrode layer 208 can vary and range from 10 Å to 1000 Å. Here, the gate electrode 208 may extend outside the gate dielectric layer 206 and into a region above a source or drain region of the MOSFET device. As shown a STI region surrounds the gate dielectric layer 206 and gate electrode 208 for dielectric insulation. In this example, the gate dielectric layer 206 is patterned to have its edge, e.g., labeled as mask position of FIG. 1, disposed between the channel and corresponding contact (e.g., a drain contact). This mask position of gate dielectric layer 206 may impact a grading effect in both of the substrate 202 and gate coupling.

In a next fabrication step, a photolithography technology and another mask can be applied to define the channel edge and remove the gate electrode above the LDD region, as shown in FIG. 2B. For example, a hard mask layer can be deposited above the string driver device 200 and patterned to expose the gate electrode 208 disposed above a defined LDD region. A selective or anisotropic etch process such as reactive ion etching (RIE) or plasma assisted etching process can be utilized to remove a portion of the gate electrode 208 that extends/overhangs above the gate dielectric layer 206. There may be residue/additional gate electrode material 208a leftover above the source region or drain region. This etching process exposes a surface of the substrate 202. Further, an ion implantation process can be utilized to lightly implant certain dopant materials in to the LDD region. In this example, the LDD region may exist under the source/drain regions, as well as the region between the source/drain regions and the channel region. After the ion implantation, dielectric material such as silicon oxide can be filled back into the gate recessed region. A chemical mechanical polishing (CMP) process can be also utilized to planarize a top surface of the dielectric material in order to form a flat surface on the string driver device 200. In addition, a wet etch process can be adopted to recess the filled dielectric material, making its top surface lower than the upper surface of the gate electrode 208.

In a following fabrication step, a field plate layer 210 can be deposited and patterned on the frontside surface of the string driver device 200. As shown in FIG. 2C, a metal field plate layer can be deposited above the gate electrode 208, the dielectric material 212, and the residue gate electrode 208a. A photolithography patterning process can be applied to pattern the original deposited metal field plate layer. As shown, the metal field plate layer can be patterned to has its edge under lapped to corresponding source/drain contact (in this example, the residue gate electrode 208a). Similar to the field plate layer 110, the metal field plate layer 210 in this example can be made of materials including tungsten, aluminum, tungsten silicon alloy, aluminum silicon alloy, or silicide. With this configuration, the edge of the metal field plate is positioned to the LDD region and away from the channel edge.

Once the process on metal field plate is completed, the residue gate electrode 208a that dispose above the source region or drain region can be etched away, e.g., using a selective wet etching process to remove residue polysilicon gate. As shown in FIG. 2D, another ion implantation process can be conducted to form contact implant and to separate the LDD region and GLDD region as labeled. In this example, the GLDD region and LDD region can be self-aligned according to the location of residue gate electrode 208a.

In a next fabrication process and as shown in FIG. 2E, a drain region 214 and a drain contact 222 can be formed above the LDD region 216 and the substrate 202. Similar, another source region and source region contact can be formed in an opposite side of the channel. Specifically, dielectric material such as silicon oxide can be deposited above the source region and the drain region and then patterned to form trenches. After that, conductive material can be filled into the trenches to form the source region contact or the drain region contact structures. In some other examples, various methods of forming the source contact and drain contact can be performed, including metal silicide contacts, self-aligned silicide process, selective epitaxial growth, lift-off technique, plug process, and atomic layer deposition (ALD) process.

In this example, the dielectric material can be identified as a first dielectric region 212a that is disposed under the overhanging field plate layer 210 and between the semiconductor channel edge and corresponding drain contact 222. Further, the dielectric material 212 also includes a second dielectric region 212b that is disposed between the field plate layer edge and corresponding drain contact 222. The second dielectric region 212b may comprise the same or different materials as the first dielectric region 212a and may provide additional insulation and spacing between the field plate layer 210 and the drain contact 222 to enhance the string driver device 200 breakdown performance.

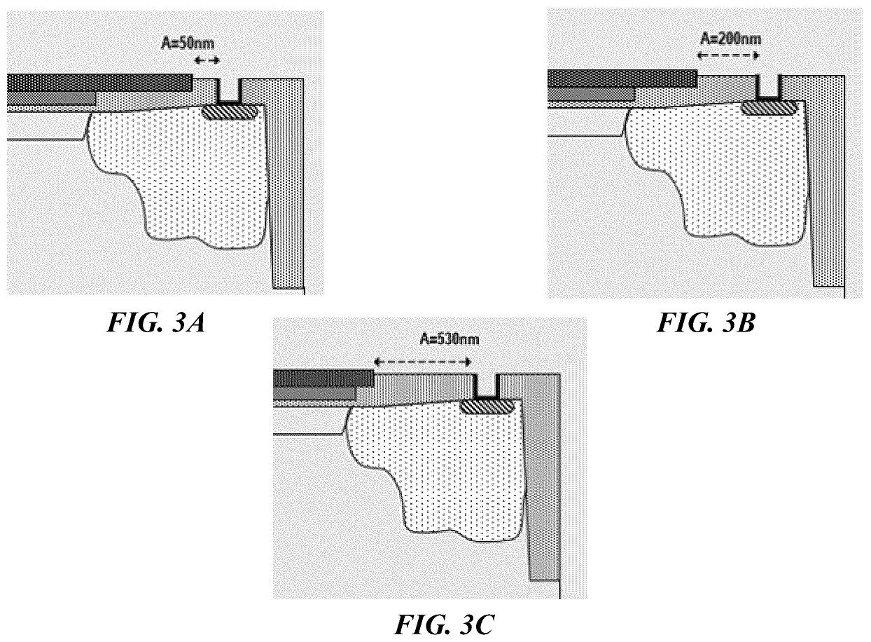

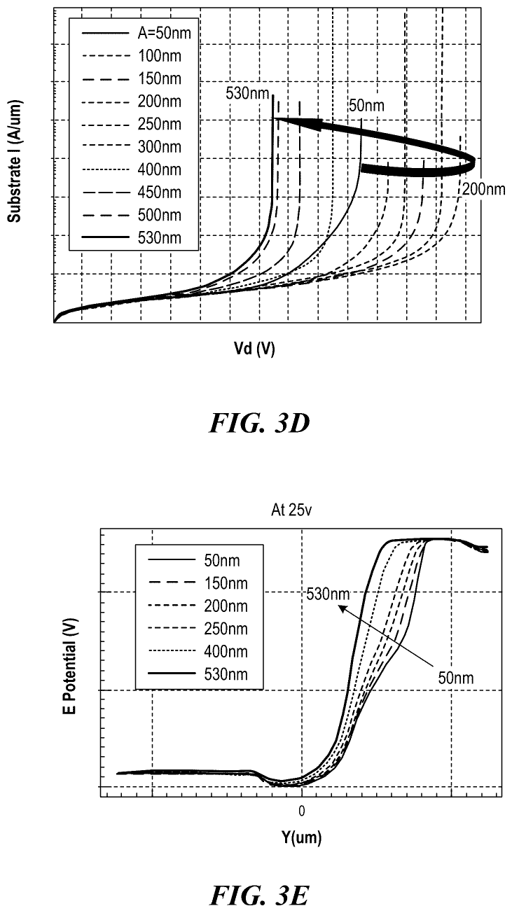

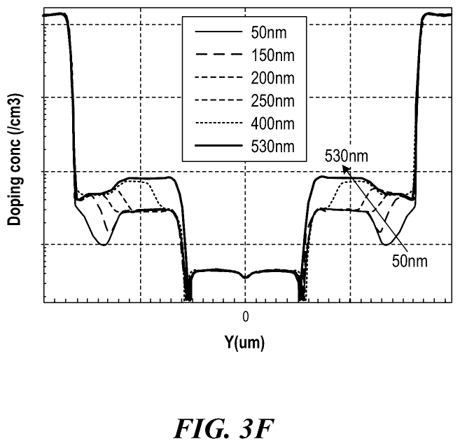

FIGS. 3A to 3F illustrate impacts of field plate to contact distance on string driver MOSFET device performance in accordance with various embodiments of the present technology. FIGS. 3A, 3B, and 3C provide string driver MOSFET device TCAD simulation results with the distance between the field plate and corresponding source contact or drain contact being equal to 50 nm, 200 nm, and 530 nm, respectively. In this simulation, the GLDD region and LDD region are configured to have doping levels close to 5×10¹² ions·cm⁻² and 4.8×10¹² ions·cm⁻², respectively. In this example, the MOSFET device having a field plate to contact distance substantially equal to 200 nm shows a highest breakdown voltage close to 26V. Specifically, as shown in FIG. 3D, the breakdown voltage curve turns around, e.g., the breakdown voltage increases as the field plate to contact distance increases from 50 nm to 200 nm and then the breakdown voltage starts to decrease as the field plate to contact distance continually increases from 200 nm to 530 nm. In addition, FIG. 3E shows the string driver device electrostatic potential change with field plate to contact distance varies. In this example, the potential drops near N+ region (e.g., the LDD region) is faster for small field plate to contact distance, whereas with large field plate to contact distance (e.g., 530 nm), fast potential drop is near the edge of the gate electrode. Therefore, both small and large field plate to contact distance reduces breakdown voltage of the string driver device. Further, a uniform electrostatic potential can be achieved with an optimum field plate to contact distance of 200 nm. FIG. 3F shows simulation results of doping concentration at a doping level of 5×10¹² ions·cm⁻², as functions of various field plate to contact distances. It can be found that in the self-aligned field plate structure disclosed in the present technology, the doping concentration can be slightly different with different field plate to contact distances.

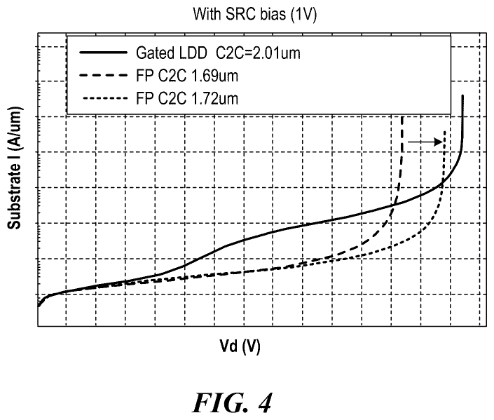

FIG. 4 illustrates impacts of contact to contact distance on string driver MOSFET device performance in accordance with various embodiments of the present technology. For example, it can be found in FIG. 4 that the larger contact to contact distance enhances the break down voltage for about 3V. For comparison purposes, FIG. 4 also includes a breakdown voltage curve generated on a MOSFET device that has similar field plate length and gate electrode length.

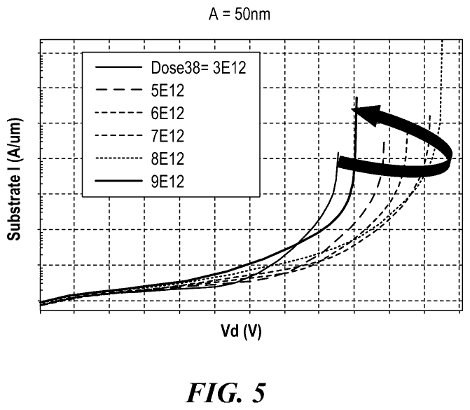

FIG. 5 illustrates impacts of ion implantation process on string driver MOSFET device performance in accordance with various embodiments of the present technology. In this example, the field plate to contact distance is fixed at 50 nm. The GLLD dose level is migrated from 5×10¹² ions·cm⁻² to 4.8×10¹² ions·cm⁻², respectively. Here, the GLLD implantation condition is modified to generate a doping level of 9×10¹² ions·cm⁻². A similar breakdown voltage turn around can be found in FIG. 5 as the impact ionization moves from N+ edge to gate edge region. More particularly, as lower level dose, the impact ionization happens at LDD junction region. While the dose level increases, the breakdown voltage of the string driver device is more limited by the impact ionization under the gate edge region.

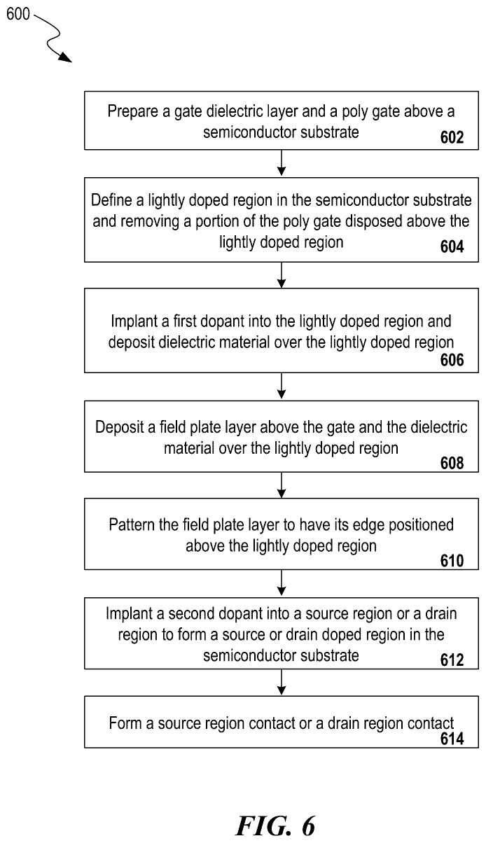

FIG. 6 describes a method 600 of fabricating the metal gated LDD string driver device according to various embodiments of the present technology. For example, the method 600 includes preparing a gate dielectric layer and a poly gate above a semiconductor substrate, at 602. For example, the gate dielectric layer 206 and the gate electrode layer 208 can be deposited on a semiconductor substrate 202, as shown in FIG. 2A.

The method 600 also includes defining a lightly doped region in the semiconductor substrate and removing a portion of the poly gate disposed above the lightly doped region, at 604. For example, a lithography technology and a patterning process can be conducted to recess a portion of the gate electrode 208 as shown in FIG. 2B. There may be residue gate electrode left above corresponding source region or drain region after the gate etching process.

In addition, the method 600 includes implanting a first dopant into the lightly doped region and deposit dielectric material over the lightly doped region, at 606. For example, dopant materials such as N type dopant material can be implanted into the semiconductor substrate through the exposed region shown in FIG. 2B. In addition, dielectric material such as silicon oxide can be filled into the exposed region for dielectric isolation.

The method 600 further includes depositing a field plate layer above the gate and the dielectric material over the lightly doped region, at 608. Further, the method 600 includes patterning the field plate layer to have its edge positioned above the lightly doped region, at 610. For example, the metal field plate layer 210 can be deposited and patterned above the gate electrode 208, the dielectric material 212, as shown in FIG. 2D. In particular, the edge of the patterned metal field plate layer 210 is underlapped with the LDD region 216.

The method 600 also includes implanting a second dopant into a source region or a drain region to form a source or drain doped region in the semiconductor substrate, at 612. For example, a second ion implantation process can be conducted to form the LDD region 216 and the GLDD region 218, as illustrated in FIG. 2D.

Lastly, the method 600 includes forming a source region contact or a drain region contact, at 614. For example, the drain contact 222 can be formed above the LDD region 216, as illustrated in FIG. 2E. In this example, the drain contact 222 is away from the edge of the metal field plate layer 210 and isolated by the second dielectric region 212b.

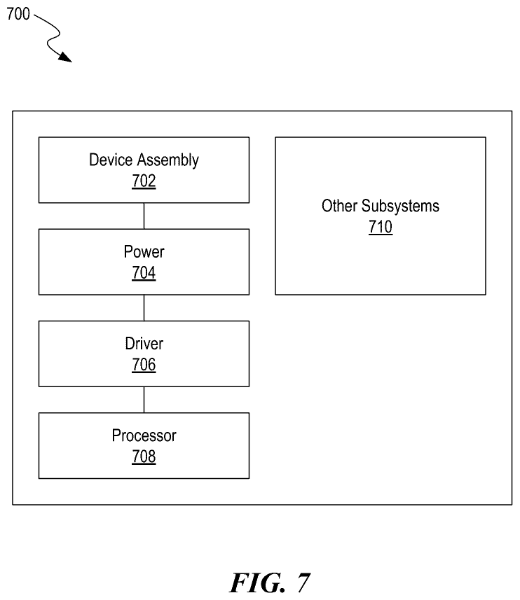

Any one of the string driver devices and semiconductor MOSFET devices described above with reference to FIGS. 1 to 6 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the string driver devices and MOSFET devices described above with reference to FIGS. 1 to 6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 700 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A string driver device, comprising:
a semiconductor substrate;
a semiconductor channel disposed in an upper portion of the semiconductor substrate;
a gate dielectric layer disposed above the semiconductor channel;
a source region and a drain region disposed at opposite sides of the semiconductor channel, each of the source region and the drain region having a corresponding contact disposed thereon;
a gate that is disposed above the gate dielectric layer and has a first length; and
a field plate layer disposed above the gate, the field plate layer having a second length larger than the first length of the gate, wherein the field plate layer includes one or more edge regions extending across the semiconductor channel edge and toward the source region or the drain region.

2. The string driver device of claim 1, further comprises a first dielectric region disposed under the one or more edge regions of the field plate layer and between the semiconductor channel edge and corresponding source region contact or drain region contact.

3. The string driver device of claim 2, further comprises a lightly doped region and a source or drain doped region in the semiconductor substrate.

4. The string driver device of claim 3, wherein the first dielectric region isolates the field plate layer from the lightly doped region.

5. The string driver device of claim 2, further comprises a second dielectric region disposed between the field plate layer edge and corresponding source region contact or drain region contact.

6. The string driver device of claim 5, wherein each of the first dielectric region and the second dielectric region comprises tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof.

7. The string driver device of claim 5, wherein the second dielectric region has a third length along a horizontal direction from the field plate layer edge and corresponding source region contact or drain region contact, the third length ranging from 10 nm to 1000 nm.

8. The string driver device of claim 1, wherein each of the one or more edge regions of the field plate layer has a fourth length ranging from 10 nm to 1000 nm.

9. The string driver device of claim 1, wherein the gate dielectric layer comprises silicon oxide (SiO), hafnium oxide (HfO), aluminum oxide (Al₂O₃), silico nitride (Si₃N₄), lanthanum oxide (La₂O₃), titanium oxide (TiO₂), or a combination thereof.

10. The string driver device of claim 1, wherein the gate comprises polysilicon.

11. The string driver device of claim 1, wherein the field plate layer comprises tungsten, aluminum, tungsten silicon alloy, aluminum silicon alloy, or silicide materials.

12. The string driver device of claim 1, wherein the first length of the gate is equal to or larger than a fifth length of the semiconductor channel.

13. The string driver device of claim 1, wherein a sixth length between an edge of the gate and corresponding source contact or drain contact is equal to or less than 700 nm.

14. A string driver device, comprising:
a gate dielectric layer disclosed above a semiconductor channel;
a first dielectric region disposed adjacent to the gate dielectric layer and directly connected to a field plate layer, wherein the dielectric region is disposed underneath the field plate layer; and
a second dielectric region disposed between the field plate layer and a corresponding source contact or a drain contact, wherein the first and second dielectric regions are connected to each other.

15. A method of forming a string driver device, comprising:
preparing a gate dielectric layer and a poly gate above a semiconductor substrate;
defining a lightly doped region in the semiconductor substrate and removing a portion of the poly gate disposed above the lightly doped region;
implanting a first dopant into the lightly doped region and deposit dielectric material over the lightly doped region;
depositing a field plate layer above the gate and the dielectric material over the lightly doped region;
patterning the field plate layer to have its edge positioned above the lightly doped region;
implanting a second dopant into a source region or a drain region to form a source or drain doped region in the semiconductor substrate; and
forming a source region contact or a drain region contact.

16. The method of claim 15, wherein defining a lightly doped region comprises forming a hard mask layer and patterning the hard mask layer to expose the lightly doped region.

17. The method of claim 16, wherein removing a portion of the poly gate disposed above the lightly doped region comprises anisotropic etching the poly gate above the exposed lightly doped region.

18. The method of claim 15, further comprising removing, before implanting the second dopants, gate material disposed above the source region and the drain region.

19. The method of claim 15, wherein forming the source region contact or the drain region contact comprises:
depositing dielectric material above the source region and the drain region;
etching the dielectric material to form trenches; and
filling conductive material into the trenches to form the source region contact or the drain region contact.

20. The method of claim 15, wherein patterning the field plate layer comprising patterning the field plate layer to have the patterned field plate layer to cover at least a portion of the gate and a portion of the lightly doped region.
